(19) United States
(12) Patent Application Publication
(10) Pub. No.: US 2017/0069693 A1
(43) Pub. Date: Mar. 9, 2017

(54) OLED PIXEL STRUCTURE, DISPLAY SUBSTRATE AND DISPLAY DEVICE

(71) Applicant: BOE TECHNOLOGY GROUP CO., LTD., Beijing (CN)

(72) Inventors: Can ZHANG, Beijing (CN); Xiaodan JIN, Beijing (CN)

(73) Assignee: BOE TECHNOLOGY GROUP CO., LTD., Beijing (CN)

(21) Appl. No.: 15/146,452

(22) Filed: May 4, 2016

(30) Foreign Application Priority Data
Sep. 8, 2015 (CN) 201510567384.X

(51) Int. Cl. H01L 27/32; H01L 51/50

(52) U.S. Cl. CPC H01L 27/3211; H01L 51/5036

(57) ABSTRACT

An OLED pixel structure is provided, it includes a plurality of pixel units arranged in a matrix form. Each pixel unit includes at least two subpixels arranged in an identical row and adjacent to each other, or at least two subpixels arranged in an identical column and adjacent to each other. Each subpixel includes a transparent region and a nontransparent region where a display element is arranged. In each pixel unit, the nontransparent regions of the at least two subpixels arranged in an identical row and adjacent to each other have their central lines in a row direction located on different straight lines parallel to each other, or the nontransparent regions of the at least two subpixels arranged in an identical column and adjacent to each other have their central lines in a column direction located on different straight lines parallel to each other.

### CROSS-REFERENCE TO RELATED APPLICATION

The present application claims a priority of the Chinese patent application No. 201510567384.X filed on Sep. 8, 2015, which is incorporated herein by reference in its entirety.

### TECHNICAL FIELD

The present disclosure relates to the field of display technology, in particular to an organic light-emitting diode (OLED) pixel structure, a display substrate and a display device.

### BACKGROUND

As a new display technology, a transparent display technology may be used to enable a viewer to view, through a screen, a background image behind the screen. Due to such a display effect, the transparent display technology may be applied to various display devices, e.g., mobile phones, lap-top computers, show-window displays, refrigerator doors, on-vehicle displays, billboards, and so on.

### SUMMARY

An object of the present disclosure is to provide an OLED pixel structure, a display substrate and a display device, so as to improve a display effect of a transparent OLED display device in the case of constant light transmittance.

In one aspect, the present disclosure provides in some embodiments an OLED pixel structure, including a plurality of pixel units arranged in a matrix form. Each pixel unit includes at least two subpixels arranged in an identical row and adjacent to each other, or at least two subpixels arranged in an identical column and adjacent to each other. Each subpixel includes a transparent region and a nontransparent region where a display element is arranged. In each pixel unit, the nontransparent regions of the at least two subpixels arranged in an identical row and adjacent to each other have their central lines in a row direction located on different straight lines parallel to each other, or the nontransparent regions of the at least two subpixels arranged in an identical column and adjacent to each other have their central lines in a column direction located on different straight lines parallel to each other.

Further, each pixel unit includes a first subpixel, a second subpixel and a third subpixels arranged sequentially and in different colors.

Further, a nontransparent region of the first subpixel and a nontransparent region of the second subpixel have their central lines in the row direction located on different straight lines parallel to each other, and the nontransparent region of the first subpixel and a nontransparent region of the third subpixel have their central lines in the row direction located on an identical straight line; or, the nontransparent region of the first subpixel and the nontransparent region of the second subpixel have their central lines in the column direction located on different straight lines parallel to each other, and the nontransparent region of the first subpixel and the nontransparent region of the third subpixel have their central lines in the column direction located on an identical straight line.

Further, the nontransparent region of the first subpixel and the nontransparent region of the third subpixel have their central lines in the row direction located on different straight lines parallel to each other, and the nontransparent region of the first subpixel and the nontransparent region of the second subpixel have their central lines in the row direction located on an identical straight line; or, the nontransparent region of the first subpixel and the nontransparent region of the third subpixel have their central lines in the column direction located on different straight lines parallel to each other, and the nontransparent region of the first subpixel and the nontransparent region of the second subpixel have their central lines in the column direction located on an identical straight line.

Further, the nontransparent region of the first subpixel and the nontransparent region of the second subpixel have their central lines in the row direction located on different straight lines parallel to each other, and the nontransparent region of the second subpixel and the nontransparent region of the third subpixel have their central lines in the row direction located on an identical line; or, the nontransparent region of the first subpixel and the nontransparent region of the second subpixel have their central lines in the column direction located on different straight line parallel to each other, and the nontransparent region of the second subpixel and the nontransparent region of the third subpixel have their central lines in the column direction located on an identical straight line.

Further, the nontransparent region of the first subpixel has its central line in the row direction located on a first straight line, the nontransparent region of the second subpixel has its central line in the row direction located on a second straight line, the nontransparent region of the third subpixel has its central line in the row direction located on a third straight line, and the first straight line, the second straight line and the third straight line in the row direction are parallel to each other; or, the nontransparent region of the first subpixel has its central line in the column direction located on a first straight line, the nontransparent region of the second subpixel has its central line in the column direction located on a second straight line, the nontransparent region of the third subpixel has its central line in the column direction located on a third straight line, and the first straight line, the second straight line and the third straight line in the column direction are parallel to each other.

Further, the second straight line is located between the first straight line and the third straight line, and a distance between the first straight line and the second straight line is equal to a distance between the second straight line and the third straight line.

Alternatively, the first subpixel is a red subpixel, a green subpixel or a blue subpixel, the second subpixel is a red subpixel, a green subpixel or a blue subpixel, and the third subpixel is a red subpixel, a green subpixel or a blue subpixel.

In another aspect, the present disclosure provides in some embodiments a display substrate including the above-mentioned OLED pixel structure.

In yet another aspect, the present disclosure provides in some embodiments a display device including the above-mentioned display substrate.

According to the embodiments of the present disclosure, in each pixel unit, the nontransparent regions of the at least two subpixels in an identical row have their central lines in the row direction located on different straight lines parallel to each other, or the nontransparent regions of the at least two subpixels in an identical column have their central lines in the column direction located on different straight lines parallel to each other. As a result, it is able to arrange the subpixels in each pixel unit in an alternate manner in the case of the constant light transmittance, and prevent the occurrence of the alternate bright and dark stripes, thereby to improve a display effect of the display device.

### BRIEF DESCRIPTION OF THE DRAWINGS

FIG. 1 is a schematic view showing a transparent OLED display device in the related art;

FIG. 2 is a schematic view showing an original image;

FIG. 3 is a schematic view showing an image obtained when the original image in FIG. 2 is displayed by the transparent OLED display device in the related art;

FIG. 4 is a schematic view showing an OLED pixel structure according to one embodiment of the present disclosure;

FIG. 5 is another schematic view showing the OLED pixel structure according to one embodiment of the present disclosure;

FIG. 6 is yet another schematic view showing the OLED pixel structure according to one embodiment of the present disclosure;

FIG. 7 is still yet another schematic view showing the OLED pixel structure according to one embodiment of the present disclosure;

FIG. 8 is still yet another schematic view showing the OLED pixel structure according to one embodiment of the present disclosure;

FIG. 9 is still yet another schematic view showing the OLED pixel structure according to one embodiment of the present disclosure; and

FIG. 10 is a schematic view showing an image obtained when the original image in FIG. 2 is displayed by a display device according to one embodiment of the present disclosure.

### DETAILED DESCRIPTION OF THE EMBODIMENTS

In order to make the objects, the technical solutions and the advantages of the present disclosure more apparent, the present disclosure will be described hereinafter in conjunction with the drawings and embodiments.

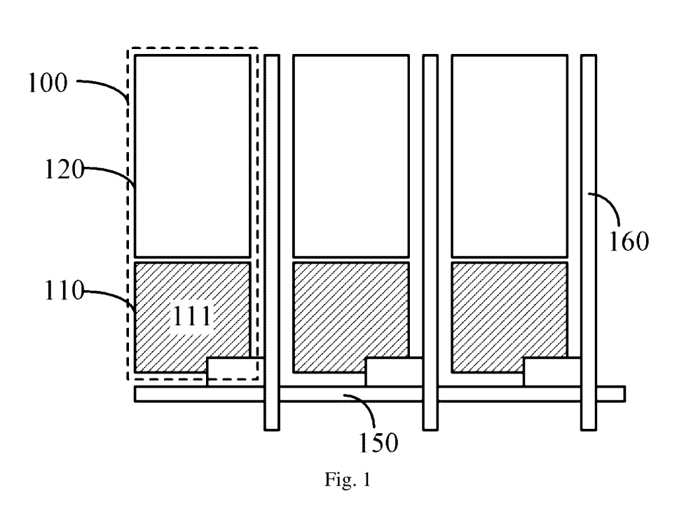

FIG. 1 schematically shows a transparent OLED display device in the related art, which includes a plurality of OLED subpixels 100 defined by gate lines 150 and data lines 160. Each OLED subpixel 100 includes a nontransparent region 110 and a transparent region 120. Usually, a display element 111 is arranged at the nontransparent region 110. During the operation of the transparent display device, the display element 111 emits light toward the transparent region 120, so as to achieve a transparent display function. No pixel structure is arranged at the transparent region 120, so that the light from the display element 111 can pass through the transparent region.

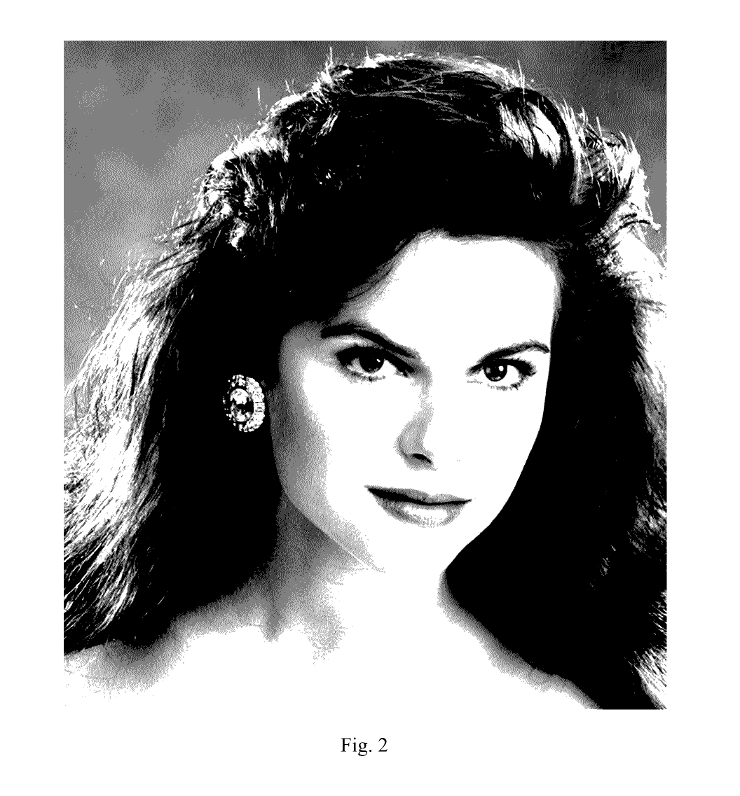

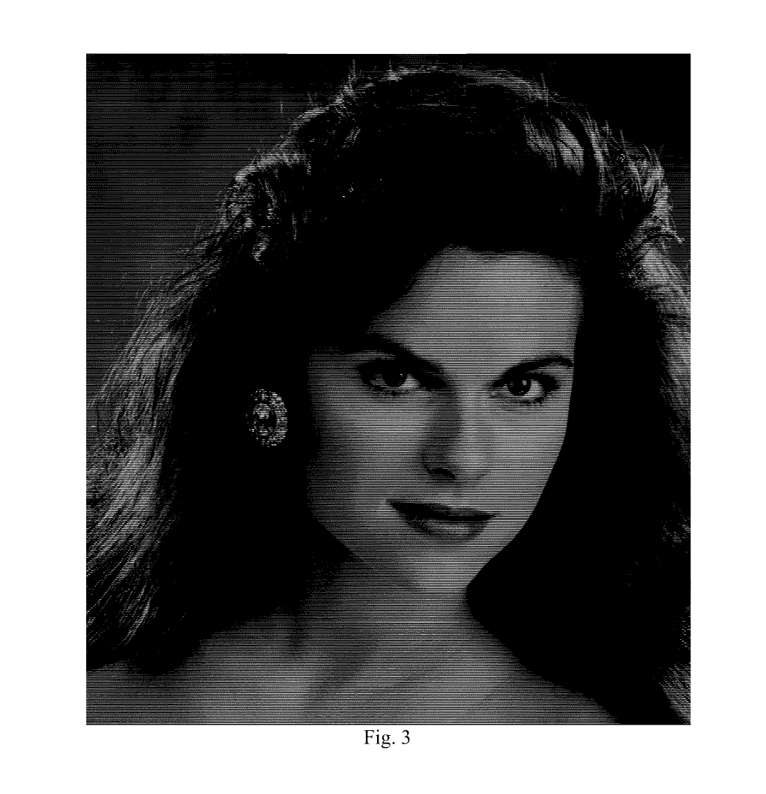

However, when an image is displayed, such a visual effect as alternate bright and dark stripes may occur. As shown in FIG. 3, which shows an image obtained when an original image in FIG. 2 is displayed by the transparent OLED display device, due to an existing pixel structure, the above-mentioned visual effect is particularly obvious when the display device has a low pixels per inch (PPI).

In order to overcome this visual effect drawback, the present disclosure provides in some embodiments an OLED pixel structure, a display substrate and a display device, so as to improve a display effect of the transparent OLED display device in the case of constant light transmittance.

The OLED pixel structure in some embodiments of the present disclosure includes a plurality of pixel units arranged in a matrix form. Each pixel unit includes at least two subpixels arranged in an identical row and adjacent to each other, or at least two subpixels arranged in an identical column and adjacent to each other. Each subpixel includes a transparent region and a nontransparent region where a display element is arranged.

In each pixel unit, the nontransparent regions of the at least two subpixels arranged in an identical row and adjacent to each other have their central lines in a row direction located on different straight lines parallel to each other, or the nontransparent regions of the at least two subpixels arranged in an identical column and adjacent to each other have their central lines in a column direction located on different straight lines parallel to each other. In this way, it is able to arrange the subpixels of each subpixel unit in an alternate manner in the case of the constant light transmittance, thereby to prevent the occurrence of such a visual effect as alternate bright and dark stripes, and improve the display effect of the display device.

Further, in some embodiments of the present disclosure, each pixel unit includes a first subpixel, a second subpixel and a third subpixels arranged sequentially and in different colors.

Further, in an alternative embodiment of the present disclosure, the three subpixels in each pixel unit may be arranged as follows. a nontransparent region of the first subpixel and a nontransparent region of the second subpixel have their central lines in the row direction located on different straight lines parallel to each other, and the nontransparent region of the first subpixel and a nontransparent region of the third subpixel have their central lines in the row direction located on an identical straight line; or, the nontransparent region of the first subpixel and the nontransparent region of the second subpixel have their central lines in the column direction located on different straight lines parallel to each other, and the nontransparent region of the first subpixel and the nontransparent region of the third subpixel have their central lines in the column direction located on an identical straight line.

Further, in another alternative embodiment of the present disclosure, the three subpixels in each subpixel unit may also be arranged as follows. the nontransparent region of the first subpixel and the nontransparent region of the third subpixel have their central lines in the row direction located on different straight lines parallel to each other, and the nontransparent region of the first subpixel and the nontransparent region of the second subpixel have their central lines in the row direction located on an identical straight line; or, the nontransparent region of the first subpixel and the nontransparent region of the third subpixel have their central lines in the column direction located on different straight lines parallel to each other, and the nontransparent region of the first subpixel and the nontransparent region of the second subpixel have their central lines in the column direction located on an identical straight line.

Further, in yet another alternative embodiment of the present disclosure, the three subpixels in each pixel unit may also be arranged as follows. the nontransparent region of the first subpixel and the nontransparent region of the second subpixel have their central lines in the row direction located on different straight lines parallel to each other, and the nontransparent region of the second subpixel and the nontransparent region of the third subpixel have their central lines in the row direction located on an identical line; or, the nontransparent region of the first subpixel and the nontransparent region of the second subpixel have their central lines in the column direction located on different straight line parallel to each other, and the nontransparent region of the second subpixel and the nontransparent region of the third subpixel have their central lines in the column direction located on an identical straight line.

To be specific, the three subpixels in each pixel unit may be arranged as follows. the nontransparent region of the first subpixel has its central line in the row direction located on a first straight line, the nontransparent region of the second subpixel has its central line in the row direction located on a second straight line, the nontransparent region of the third subpixel has its central line in the row direction located on a third straight line, and the first straight line, the second straight line and the third straight line in the row direction are parallel to each other; or, the nontransparent region of the first subpixel has its central line in the column direction located on a first straight line, the nontransparent region of the second subpixel has its central line in the column direction located on a second straight line, the nontransparent region of the third subpixel has its central line in the column direction located on a third straight line, and the first straight line, the second straight line and the third straight line in the column direction are parallel to each other. In this way, the first subpixel, the second subpixel and the third subpixel are arranged regularly.

Alternatively, the second straight line is located between the first straight line and the third straight line, and a distance between the first straight line and the second straight line is equal to a distance between the second straight line and the third straight line. In this way, the subpixels in each pixel unit are arranged alternately and at an identical interval, so as to further prevent the occurrence of the alternate bright and dark stripes, thereby to improve the display effect of the display device.

To be specific, the first subpixel is a red subpixel, a green subpixel or a blue subpixel, the second subpixel is a red subpixel, a green subpixel or a blue subpixel, and the third subpixel is a red subpixel, a green subpixel or a blue subpixel.

The present disclosure further provides in some embodiments a display substrate which includes the above-mentioned OLED pixel structure.

According to the display substrate in the embodiments of the present disclosure, in each pixel unit, the nontransparent regions of the at least two subpixels arranged in an identical row and adjacent to each other have their central lines in a row direction located on different straight lines parallel to each other, or the nontransparent regions of the at least two subpixels arranged in an identical column and adjacent to each other have their central lines in a column direction located on different straight lines parallel to each other. In this way, it is able to arrange the subpixels in each pixel unit alternately in the case of the constant light transmittance, thereby to prevent the occurrence of the alternate bright and dark stripes, and improve the display effect of the display device.

The present disclosure further provides in some embodiments a display device, which includes the above-mentioned display substrate. The display device may be any product or member having a display function, such as a television, a display, a digital photo frame, a mobile phone or a flat-panel computer.

According to the display device in the embodiments of the present disclosure, in each pixel unit, the nontransparent regions of the at least two subpixels arranged in an identical row and adjacent to each other have their central lines in a row direction located on different straight lines parallel to each other, or the nontransparent regions of the at least two subpixels arranged in an identical column and adjacent to each other have their central lines in a column direction located on different straight lines parallel to each other. In this way, it is able to arrange the subpixels in each pixel unit alternately in the case of the constant light transmittance, thereby to prevent the occurrence of the alternate bright and dark stripes, and improve the display effect of the display device.

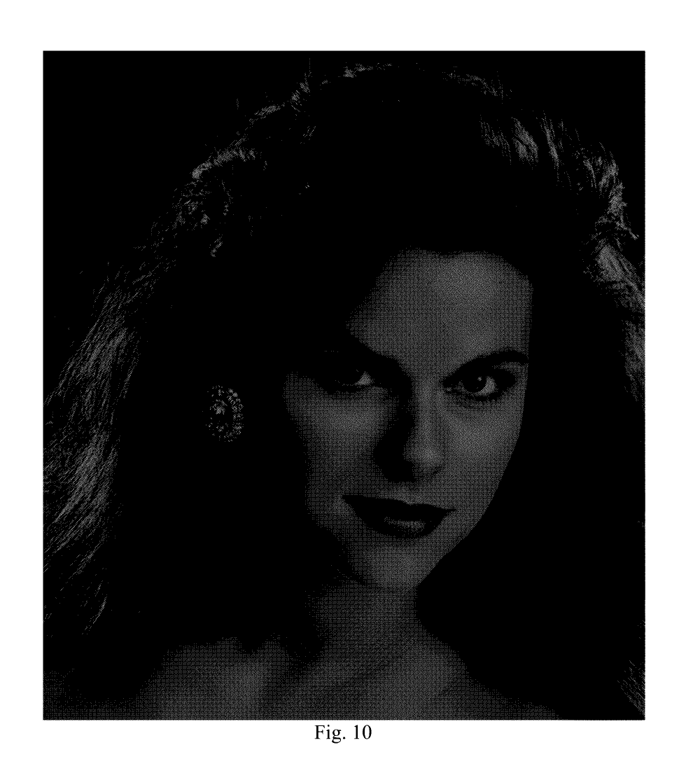

FIG. 4 shows the OLED pixel structure for the display device according to one embodiment of the present disclosure. Each pixel unit includes a blue subpixel 170, a green subpixel 180 and a red subpixel 190 arranged sequentially in the row direction, and each subpixel includes a nontransparent region and a transparent region. The nontransparent region of the blue subpixel 180 has its central line in the row direction located on a first straight line, the nontransparent region of the green subpixel 180 has its central line in the row direction located on a second straight line, and the nontransparent region of the red subpixel 190 has its central line in the row direction located on a third straight line. The first straight line, the second straight line and the third straight line are parallel to each other. The second straight line is arranged between the first straight line and the third straight line, and a distance between the first straight line and the second straight line is equal to a distance between the second straight line and the third straight line. In this way, the subpixels in each pixel unit are arranged alternately and at an identical interval in the case of the constant light transmittance. FIG. 10 shows an image obtained when the original image in FIG. 2 is displayed by the display device in the embodiments of the present disclosure. As compared with FIG. 3, it is able to remarkably prevent the occurrence of the alternate bright and dark stripes, thereby to remarkably improve the display effect of the display device.

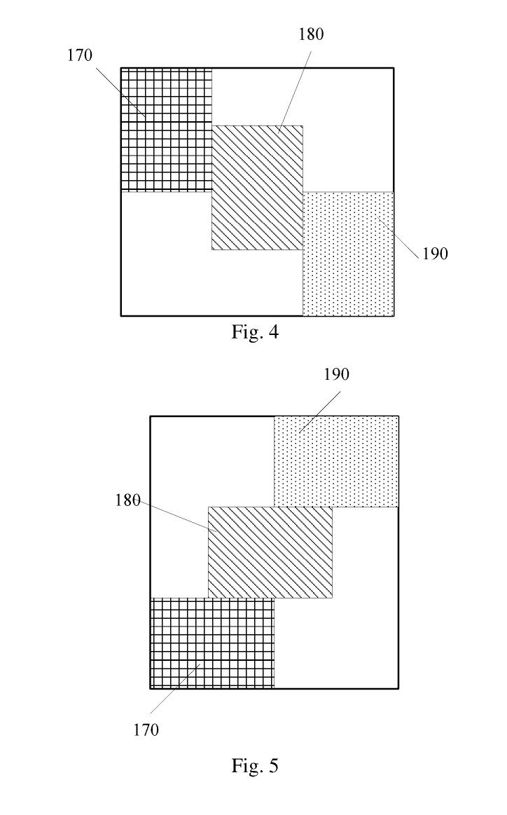

FIG. 5 shows the OLED pixel structure for the display device according to one embodiment of the present disclosure. Each pixel unit includes the blue subpixel 170, the green subpixel 180 and the red subpixel 190 arranged sequentially in the column direction, and each subpixel includes the nontransparent region and the transparent region. The nontransparent region of the blue subpixel 180 has its central line in the column direction located on a first straight line, the nontransparent region of the green subpixel 180 has its central line in the column direction located on a second straight line, and the nontransparent region of the red subpixel 190 has its central line in the column direction located on a third straight line. The first straight line, the second straight line and the third straight line are parallel to each other. The second straight line is arranged between the first straight line and the third straight line, a distance between the first straight line and the second straight line is equal to a distance between the second straight line and the third straight line. In this way, the subpixels in each pixel unit are arranged alternately and at an identical interval in the case of the constant light transmittance. FIG. 10 shows an image obtained when the original image in FIG. 2 is displayed by the display device in the embodiments of the present disclosure. As compared with FIG. 3, it is able to remarkably prevent the occurrence of the alternate bright and dark stripes, thereby to remarkably improve the display effect of the display device.

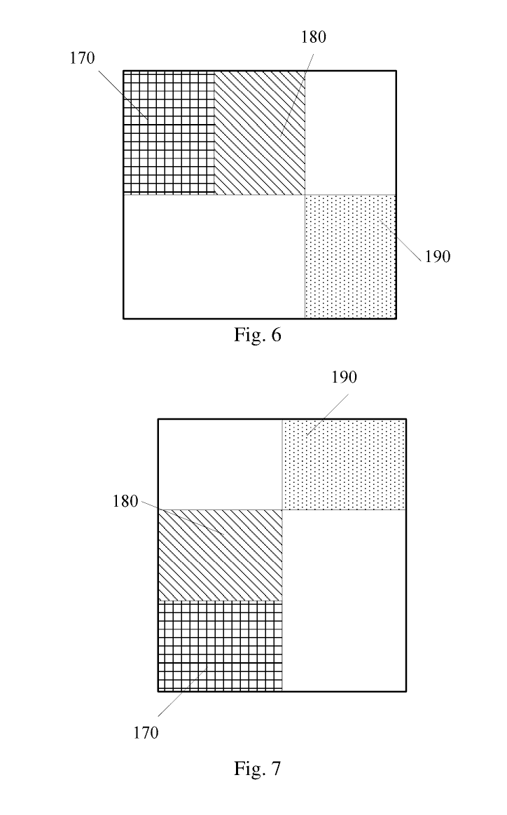

FIG. 6 shows the OLED pixel structure for the display device according to one embodiment of the present disclosure. Each pixel unit includes the blue subpixel 170, the green subpixel 180 and the red subpixel 190 arranged sequentially in the row direction, and each subpixel includes the nontransparent region and the transparent region. The nontransparent region of the blue subpixel 170 has its central line in the row direction located on a first straight line, the nontransparent region of the green subpixel 180 has its central line in the row direction located on a second straight line, and the nontransparent region of the red subpixel 190 has its central line in the row direction located on a third straight line. The first straight is identical to the second straight line, parallel to the third straight line, and spaced apart from the third straight line at a certain distance. In this way, the subpixels in each pixel unit are arranged alternately and at an identical interval in the case of the constant light transmittance. FIG. 10 shows an image obtained when the original image in FIG. 2 is displayed by the display device in the embodiments of the present disclosure. As compared with FIG. 3, it is able to remarkably prevent the occurrence of the alternate bright and dark stripes, thereby to remarkably improve the display effect of the display device.

FIG. 7 shows the OLED pixel structure for the display device according to one embodiment of the present disclosure. Each pixel unit includes the blue subpixel 170, the green subpixel 180 and the red subpixel 190 arranged sequentially in the column direction, and each pixel unit includes the nontransparent region and the transparent region. The nontransparent region of the blue subpixel 170 has its central line in the column direction located on a first straight line, the nontransparent region of the green subpixel 180 has its central line in the column direction located on a second straight line, and the nontransparent region of the red subpixel 190 has its central line in the column direction located on a third straight line. The first straight line is identical to the second straight line, parallel to the third straight line, and spaced apart from the third straight line at a certain distance. In this way, the subpixels in each pixel unit are arranged alternately and at an identical interval in the case of the constant light transmittance. FIG. 10 shows an image obtained when the original image in FIG. 2 is displayed by the display device in the embodiments of the present disclosure. As compared with FIG. 3, it is able to remarkably prevent the occurrence of the alternate bright and dark stripes, thereby to remarkably improve the display effect of the display device.

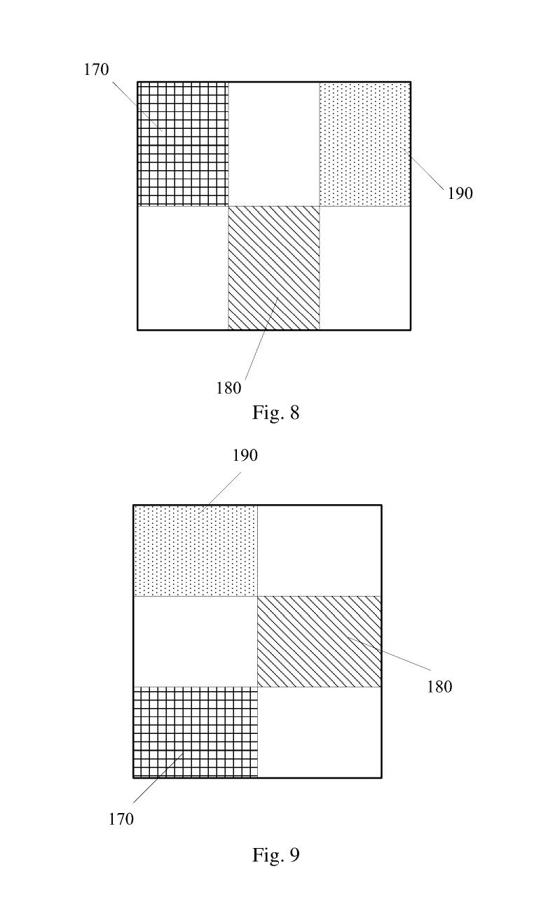

FIG. 8 shows the OLED pixel structure for the display device according to one embodiment of the present disclosure. Each pixel unit includes the blue subpixel 170, the green subpixel 180 and the red subpixel 190 arranged sequentially in the row direction, and each subpixel includes the nontransparent region and the transparent region. The nontransparent region of the blue subpixel 170 has its central line in the row direction located on a first straight line, the nontransparent region of the green subpixel 180 has its central line in the row direction located on a second straight line, and the nontransparent region of the red subpixel 190 has its central line in the row direction located on a third straight line. The first straight line is identical to the third straight line, parallel to the second straight line, and spaced apart from the second straight line at a certain distance. In this way, the subpixels in each pixel unit are arranged alternately and at an identical interval in the case of the constant light transmittance. FIG. 10 shows an image obtained when the original image in FIG. 2 is displayed by the display device in the embodiments of the present disclosure. As compared with FIG. 3, it is able to remarkably prevent the occurrence of the alternate bright and dark stripes, thereby to remarkably improve the display effect of the display device.

FIG. 9 shows the OLED pixel structure for the display device according to one embodiment of the present disclosure. Each pixel unit includes the blue subpixel 170, the green subpixel 180 and the red subpixel 190 arranged sequentially in the column direction, and each subpixel includes the nontransparent region and the transparent region. The nontransparent region of the blue subpixel 170 has its central line in the column direction located on a first straight line, the nontransparent region of the green subpixel 180 has its central line in the column direction located on a second straight line, and the nontransparent region of the red subpixel 190 has its central line in the column direction located on a third straight line. The first straight line is identical to the third straight line, parallel to the second straight line, and spaced apart from the second straight line at a certain distance. In this way, the subpixels in each pixel unit are arranged alternately and at an identical interval in the case of the constant light transmittance. FIG. 10 shows an image obtained when the original image in FIG. 2 is displayed by the display device in the embodiments of the present disclosure. As compared with FIG. 3, it is able to remarkably prevent the occurrence of the alternate bright and dark stripes, thereby to remarkably improve the display effect of the display device.

The above are merely the preferred embodiments of the present disclosure. It should be appreciated that, a person skilled in the art may make further modifications and improvements without departing from the principle of the present disclosure, and these modifications and improvements shall also fall within the scope of the present disclosure.

What is claimed is:

1. An organic light-emitting diode (OLED) pixel structure, comprising a plurality of pixel units arranged in a matrix form, each pixel unit comprising at least two subpixels arranged in an identical row and adjacent to each other, or at least two subpixels arranged in an identical column and adjacent to each other, each subpixel comprising a transparent region and a nontransparent region where a display element is arranged, wherein
in each pixel unit, the nontransparent regions of the at least two subpixels arranged in an identical row and adjacent to each other have their central lines in a row direction located on different straight lines parallel to each other, or the nontransparent regions of the at least two subpixels arranged in an identical column and adjacent to each other have their central lines in a column direction located on different straight lines parallel to each other.

2. The OLED pixel structure according to claim 1, wherein each pixel unit comprises a first subpixel, a second subpixel and a third subpixels arranged sequentially and in different colors.

3. The OLED pixel structure according to claim 2, wherein a nontransparent region of the first subpixel and a nontransparent region of the second subpixel have their central lines in the row direction located on different straight lines parallel to each other, and the nontransparent region of the first subpixel and a nontransparent region of the third subpixel have their central lines in the row direction located on an identical straight line; or
the nontransparent region of the first subpixel and the nontransparent region of the second subpixel have their central lines in the column direction located on different straight lines parallel to each other, and the nontransparent region of the first subpixel and the nontransparent region of the third subpixel have their central lines in the column direction located on an identical straight line.

4. The OLED pixel structure according to claim 2, wherein
the nontransparent region of the first subpixel and the nontransparent region of the third subpixel have their central lines in the row direction located on different straight lines parallel to each other, and the nontransparent region of the first subpixel and the nontransparent region of the second subpixel have their central lines in the row direction located on an identical straight line; or
the nontransparent region of the first subpixel and the nontransparent region of the third subpixel have their central lines in the column direction located on different straight lines parallel to each other, and the nontransparent region of the first subpixel and the nontransparent region of the second subpixel have their central lines in the column direction located on an identical straight line.

5. The OLED pixel structure according to claim 2, wherein
the nontransparent region of the first subpixel and the nontransparent region of the second subpixel have their central lines in the row direction located on different straight lines parallel to each other, and the nontransparent region of the second subpixel and the nontransparent region of the third subpixel have their central lines in the row direction located on an identical line; or
the nontransparent region of the first subpixel and the nontransparent region of the second subpixel have their central lines in the column direction located on different straight line parallel to each other, and the nontransparent region of the second subpixel and the nontransparent region of the third subpixel have their central lines in the column direction located on an identical straight line.

6. The OLED pixel structure according to claim 2, wherein
the nontransparent region of the first subpixel has its central line in the row direction located on a first straight line, the nontransparent region of the second subpixel has its central line in the row direction located on a second straight line, the nontransparent region of the third subpixel has its central line in the row direction located on a third straight line, and the first straight line, the second straight line and the third straight line in the row direction are parallel to each other; or
the nontransparent region of the first subpixel has its central line in the column direction located on a first straight line, the nontransparent region of the second subpixel has its central line in the column direction located on a second straight line, the nontransparent region of the third subpixel has its central line in the column direction located on a third straight line, and the first straight line, the second straight line and the third straight line in the column direction are parallel to each other.

7. The OLED pixel structure according to claim 6, wherein the second straight line is located between the first straight line and the third straight line, and a distance between the first straight line and the second straight line is equal to a distance between the second straight line and the third straight line.

8. The OLED pixel structure according to claim 2, wherein the first subpixel is a red subpixel, a green subpixel or a blue subpixel, the second subpixel is a red subpixel, a green subpixel or a blue subpixel, and the third subpixel is a red subpixel, a green subpixel or a blue subpixel.

9. A display substrate, comprising the organic light-emitting diode (OLED) pixel structure according to claim 1.

10. The display substrate according to claim 9, wherein each pixel unit comprises a first subpixel, a second subpixel and a third subpixel arranged sequentially and in different colors.

11. The display substrate according to claim 10, wherein
a nontransparent region of the first subpixel and a nontransparent region of the second subpixel have their central lines in the row direction located on different straight lines parallel to each other, and the nontransparent region of the first subpixel and a nontransparent region of the third subpixel have their central lines in the row direction located on an identical straight line; or
the nontransparent region of the first subpixel and the nontransparent region of the second subpixel have their central lines in the column direction located on different straight lines parallel to each other, and the nontransparent region of the first subpixel and the nontransparent region of the third subpixel have their central lines in the column direction located on an identical straight line.

12. The display substrate according to claim 10, wherein
the nontransparent region of the first subpixel and the nontransparent region of the third subpixel have their central lines in the row direction located on different straight lines parallel to each other, and the nontransparent region of the first subpixel and the nontransparent region of the second subpixel have their central lines in the row direction located on an identical straight line; or
the nontransparent region of the first subpixel and the nontransparent region of the third subpixel have their central lines in the column direction located on different straight lines parallel to each other, and the nontransparent region of the first subpixel and the nontransparent region of the second subpixel have their central lines in the column direction located on an identical straight line.

13. The display substrate according to claim 10, wherein
the nontransparent region of the first subpixel and the nontransparent region of the second subpixel have their central lines in the row direction located on different straight lines parallel to each other, and the nontransparent region of the second subpixel and the nontransparent region of the third subpixel have their central lines in the row direction located on an identical line; or
the nontransparent region of the first subpixel and the nontransparent region of the second subpixel have their central lines in the column direction located on different straight line parallel to each other, and the nontransparent region of the second subpixel and the nontransparent region of the third subpixel have their central lines in the column direction located on an identical straight line.

14. The display substrate according to claim 10, wherein
the nontransparent region of the first subpixel has its central line in the row direction located on a first straight line, the nontransparent region of the second subpixel has its central line in the row direction located on a second straight line, the nontransparent region of the third subpixel has its central line in the row direction located on a third straight line, and the first straight line, the second straight line and the third straight line in the row direction are parallel to each other; or
the nontransparent region of the first subpixel has its central line in the column direction located on a first straight line, the nontransparent region of the second subpixel has its central line in the column direction located on a second straight line, the nontransparent region of the third subpixel has its central line in the column direction located on a third straight line, and the first straight line, the second straight line and the third straight line in the column direction are parallel to each other.

15. The display substrate according to claim 14, wherein the second straight line is located between the first straight line and the third straight line, and a distance between the first straight line and the second straight line is equal to a distance between the second straight line and the third straight line.

16. The display substrate according to claim 10, wherein the first subpixel is a red subpixel, a green subpixel or a blue subpixel, the second subpixel is a red subpixel, a green subpixel or a blue subpixel, and the third subpixel is a red subpixel, a green subpixel or a blue subpixel.

17. A display device, comprising the display substrate according to claim 9.
